(19) United States
(12) Patent Application Publication
(10) Pub. No.: US 2023/0259026 A1
(43) Pub. Date: Aug. 17, 2023

(54) PHOTOSENSITIVE RESIN COMPOSITION, METHOD OF PRODUCING PATTERNED CURED PRODUCT USING THE SAME, AND CURED PRODUCT OF PHOTOSENSITIVE RESIN COMPOSITION

(71) Applicant: Showa Denko Materials Co., Ltd., Tokyo (JP)

(72) Inventors: Shinichiro ABE, Tokyo (JP); Kazuyuki MITSUKURA, Tokyo (JP); Masaya TOBA, Tokyo (JP); Yuki IMAZU, Tokyo (JP)

(21) Appl. No.: 17/823,426

(22) Filed: Aug. 30, 2022

Related U.S. Application Data
(60) Provisional application No. 63/310,121, filed on Feb. 15, 2022.

(51) Int. Cl. G03F 7/028; G03F 7/32

(52) U.S. Cl. CPC G03F 7/028; G03F 7/325

(57) ABSTRACT

A photosensitive resin composition used for forming an insulating layer includes a resin including an aromatic polyester imide structure, a photopolymerization initiator and a thermal radical polymerization initiator, and when the resin including an aromatic polyester imide structure does not include a (meth)acryl group, the resin composition includes a (meth)acryloyl compound.

### CROSS-REFERENCE TO RELATED APPLICATION

The present application claims the benefit of U.S. Provisional Application No. 63/310,121, filed on Feb. 15, 2022, the entire disclosure of which is incorporated by reference herein.

### TECHNICAL FIELD

The present disclosure relates to a photosensitive resin composition, a method of producing a patterned cured product using the same, and a cured product in which the photosensitive resin composition is used for an interlayer insulating film, a cover coat layer or a surface protective film.

### BACKGROUND ART

Conventionally, polyimide or polybenzoxazole having excellent heat resistance, an electrical property, a mechanical property, or the like has been used for a surface protective film and an interlayer insulating film of a semiconductor device. In recent years, a photosensitive resin composition having a photosensitive property imparted to these resins themselves has been used, and by using this, a producing step of a cured pattern can be simplified and the complicated producing step can be shortened (See, for example, Patent Literature 1).

On the other hand, for the purpose of high-density and high-performance of semiconductor packages, a mounting form in which chips having different performances are mixedly mounted in one package has been proposed. In this case, a high-density interconnect technique between chips, which is excellent in terms of cost, has become important (see, for example, Patent Literature 2).

Non-Patent Literature 1 and Non-Patent Literature 2 describe a package-on-package (PoP: Package on Package) mode in which different packages are connected by stacking them by flip-chip mounting on the package. This PoP is a mode widely adopted in smartphones, tablet terminals and the like.

As another form for mounting multiple chips at high-density, a packaging technology using an organic substrate having high-density wiring; fan-out type packaging technology (FO-WLP: Fan Out-Wafer Level Package) having through mold via (TMV: Through Mold Via); packaging technology using silicon or glass interposer; packaging technology using silicon through electrode (TSV: Through Silicon Via); packaging technology using chips embedded in a substrate for inter-chip transmission; and the like has been proposed.

Especially, when semiconductor chips are mounted in wiring layer for semiconductors and FO-WLP, a fine wiring layer for conducting the semiconductor chips with each other at high-density is required (see, for example, Patent Literature 3).

Furthermore, in recent years, with the advent of wearable terminals as well as smartphones and the emergence of a system called “communication that connects thing to thing” (M2M), in which devices communicate with each other without human intervention, mobile terminals has been widespread in all fields of society such as transportation, medical care, companies, public facilities, schools, homes and the like. In order to cope with such an increase in the traffic, the ultra-high speed of mobile communication and the expansion of the frequency band used have been attempted. Under such circumstances, there is an urgent need to shift to the next-generation communication standard called “5G”. (See, for example, Non-Patent Literature 3)

5G (5 Generation) is a fifth-generation mobile communication system having new features such as “ultra-high speed”, “many connections”, and “ultra-low latency”. It enables communication between mobile terminals at a speed of 10 Gbps or more, which is 100 times the communication speed of the current fourth-generation mobile communication system called 4G.

In order to achieve 5G, radio waves in frequency bands (first phase: 28 GHz or less, second phase: 100 GHz or less) higher than the current 4G (maximum frequency of about 3.5 GHz) are used, in order to transmit high-frequency radio waves with low power consumption without deterioration, the low dielectric property is required for each material that constitutes an antenna that transmits and receives radio waves (See, for example, Non-Patent Literature 4).

### PRIOR ART LITERATURE

### Patent Literature

[Patent Literature 1] Japanese Patent Application Laid-Open No. 2009-265520
[Patent Literature 2] Japanese Unexamined Patent Application Publication No. 2012-529770
[Patent Literature 3] US Patent Application Publication No. 2011/0221071

### Non-Patent Literature

[Non-patent Literature 1] Jinseong Kim et al., “Application of Through Mold Via (TMV) as PoP Base Package”, Electronic Components and Technology Conference (ECTC), p. 1089-1092 (2008)
[Non-patent Literature 2] S. W. Yoon et al., “Advanced Low Profile PoP Solution with Embedded Wafer Level PoP (eWLB-PoP) Technology”, ECTC, p. 1250-1254 (2012)
[Non-patent Literature 3] International Media Service Research Institute: “5G 5th Generation Mobile Communication System Latest Information”, 2018
[Non-patent Literature 4] Urmy Ray, “Packaging and Integration Strategy for mm-Wave Products” Proceedings of iMAPS 2018(2018).

### SUMMARY OF INVENTION

### Problems to be Solved by the Invention

A wiring layer (wiring layer for semiconductors) for mounting a plurality of semiconductor chips may be used for a build-up substrate, a wafer level package (WLP), a fan-out type PoP bottom package, and the like. For example, a polyimide resin or a polybenzoxazole resin can be used for this wiring layer, but these resins generally have a poor dielectric property, and when used as a material for a semiconductor package related to 5G, a problem such as signal deterioration or the occurrence of delay arises.

On the other hand, a polymer having an aromatic polyester skeleton exhibits liquid crystallinity like a mesogen skeleton and it is possible to attain the low dielectric property. However, the polymer is not photosensitive (photoreactive), and a patterned cured product cannot be produced by the method of Patent Literature 1 described above.

In the present disclosure, by imparting photosensitivity to this aromatic polyester skeleton, it is possible to provide a resin having both a low dielectric property and photolithography.

An object of the present disclosure is to provide a photosensitive resin composition having good performance in terms of a low dielectric property, photolithography and insulation reliability, a method of producing a patterned cured product using the resin composition, and a cured product in which the photosensitive resin composition is used for an interlayer insulating film, a cover coat layer, or a surface protective film.

### Means for Solving the Problems

The present disclosure related to [1] a photosensitive resin composition being a resin composition used for forming an insulating layer, the resin composition including a resin including an aromatic polyester imide structure represented by the following Formula (1), a photopolymerization initiator and a thermal radical polymerization initiator, in which when the resin including an aromatic polyester imide structure represented by Formula (1) does not include a group represented by the following Formula (2), the resin composition includes a (meth)acryloyl compound.

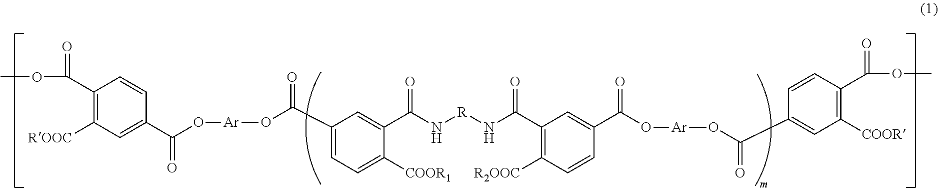

In Formula (1), m is an integer from 1 to 100, Ar is a divalent group having an aromatic skeleton, R is a divalent group having an aromatic skeleton with 2 to 30 carbon atoms and 4 to 100 hydrogen atoms, and each of —COOR₁ and —COOR₂ is positioned in an ortho position with an adjacent —CONH—, and each of R₁, R₂, and R′ independently represents a hydrogen atom, a group represented by Formula (2), or a hydrocarbon group with 1 to 4 carbon atoms.

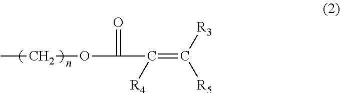

In Formula (2), each of R₃ to R₅ independently represents a hydrogen atom or an aliphatic hydrocarbon group with 1 to 3 carbon atoms, and n is an integer from 1 to 10.

The present disclosure also relates to [2] the photosensitive resin composition according to [1], further including a coupling agent.

The present disclosure also relates to [3] the photosensitive resin composition according to [1] or [2], further comprising a (meth)acryloyl compound.

The present disclosure also relates to [4] the photosensitive resin composition according to any one of [1] to [3], in which a chloride ion concentration in a cured product of the photosensitive resin composition according to any one of [1] to [3] is 5 ppm or less.

The present disclosure also relates to [5] the photosensitive resin composition according to any one of [1] to [4], in which a breaking elongation in a cured product of the photosensitive resin composition according to any one of [1] to [4] is from 10% to 200%.

The present disclosure also relates to [6] the photosensitive resin composition according to any one of [1] to [5], in which a dielectric constant at 10 GHz in a cured product of the photosensitive resin composition according to any one of [1] to [5] is 3.2 or less.

The present disclosure also relates to [7] the photosensitive resin composition according to any one of [1] to [6], in which a dissipation factor at 10 GHz in a cured product of the photosensitive resin composition according to any one of [1] to [6] is 0.0100 or less.

The present disclosure also relates to [8] the photosensitive resin composition according to any one of [1] to [7], in which a weight reduction temperature by 5% in a cured product of the photosensitive resin composition according to any one of [1] to [7] is 300° C. or more.

The present disclosure also relates to [9] the photosensitive resin composition according to any one of [1] to [8], in which a coefficient of moisture absorption in a cured product of the photosensitive resin composition, after being left in an environment of 130° C. and 85% relative humidity for 200 hours according to any one of [1] to [8] is 1% by mass or less.

The present disclosure also relates to [10] a method of producing a patterned cured product, the method including: forming a photosensitive resin film by applying the photosensitive resin composition according to any one of [1] to [9] to a substrate and drying the photosensitive resin composition, obtaining a resin film by pattern exposure of the photosensitive resin film, obtaining a patterned resin film by developing the resin film after pattern exposure, using an organic solvent, and heating the patterned resin film.

The present disclosure also relates to [11] the method of producing a patterned cured product according to [10], in which a heating temperature is 200° C. or less.

The present disclosure also relates to [12] a cured product obtained by curing the photosensitive resin composition according to any one of [1] to [9].

The present disclosure also relates to [13] the cured product according to [12], including a patterned cured product.

The present disclosure also relates to [14] the cured product according to [12] or [13], used as an interlayer insulating film, a cover coat layer or a surface protective film.

The present disclosure also relates to [15] an electronic component including the interlayer insulating film, the cover coat layer or the surface protective film according to [14].

### Effects of the Invention

According to the present disclosure, it is possible to provide a resin composition having a low dielectric constant and a low dissipation factor, capable of photolithography, and forming an insulating layer having insulation reliability. This composition has low moisture absorption, can be heat-treated at a low temperature, and is suitable for producing a patterned cured product. The cured product formed from this resin composition has a low dielectric property and low moisture absorption, and a highly reliable electronic component can be formed by applying the cured product to an interlayer insulating film, a cover coat layer or a surface protective film.

### BRIEF DESCRIPTION OF DRAWINGS

FIG. 1 is a flow drawing of a method of producing a patterned cured product according to one embodiment of the present disclosure.

FIG. 2 is a drawing showing a step of producing an electronic component according to one embodiment of the present disclosure.

### DESCRIPTION OF EMBODIMENTS

Hereinafter, embodiments of a photosensitive resin composition of the present disclosure, a method of producing a patterned cured product using it, a cured product, an interlayer insulating film, a cover coat layer, a surface protective film and an electronic component will be explained in detail. The present disclosure is not limited to the following embodiments.

In the present specification, the term “A or B” may include either A or B, and may include both A and B. Further, in the present specification, the term “step” is used not only as an independent step but also as long as the intended action of the step is achieved even if it cannot be clearly distinguished from another step.

Those numerical ranges that are expressed with “to” each denote a range that includes the numerical values stated before and after “to” as the minimum value and the maximum value, respectively. In the present specification, when there are plural kinds of substances that correspond to each component in a composition, the content amount of each component in the composition means a total amount of the plural kinds of substances existing in the composition, unless otherwise specified. Further, unless otherwise specified, the exemplary materials may be used alone or may be used in combination of two or more.

In a set of numerical ranges that are stated stepwisely, the upper limit value or the lower limit value of a numerical range may be replaced with the upper limit value or the lower limit value of other numerical range. Further, in a stated numerical range, the upper limit or the lower limit of the numerical range may be replaced with a relevant value indicated in any of Examples.

In the present specification, “(meth)acryloyl compound” means “acryloyl compound” and “methacryloyl compound”, and “(meth)acrylic group” means “acrylic group” and “methacrylic group”.

(Resin Including Aromatic Polyester Imide Structure Represented by Formula (1))

A photosensitive resin composition according to the present disclosure includes a resin (compound) including an aromatic polyester imide structure represented by the following Formula (1), a photopolymerization initiator and a thermal radical polymerization initiator, and when the resin including the aromatic polyester imide structure represented by Formula (1) does not include a group represented by the following Formula (2), the resin composition further includes a (meth)acryloyl compound. In other words, this resin composition is a photocurable (photosensitive) resin composition that is cured by light, or a thermosetting resin composition that is cured by heat. This resin composition is suitably used for forming an insulating layer such as an interlayer insulating film, a cover coat layer or a surface protective film.

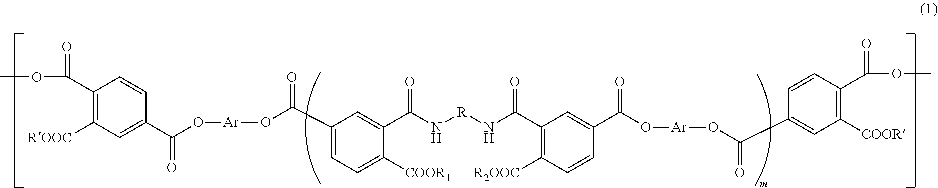

In Formula (1), m is an integer from 1 to 100, Ar is a divalent group having an aromatic skeleton, R is a divalent group having an aromatic skeleton with 2 to 30 carbon atoms and 4 to 100 hydrogen atoms, and each of —COOR₁ and —COOR₂ is positioned in an ortho position with an adjacent —CONH—, and each of R₁, R₂, and R′ independently represents a hydrogen atom, a group represented by Formula (2), or a hydrocarbon group with 1 to 4 carbon atoms.

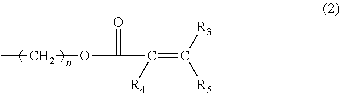

In Formula (2), each of R₃ to R₅ independently represents a hydrogen atom or an aliphatic hydrocarbon group with 1 to 3 carbon atoms, and n is an integer from 1 to 10.

The aromatic skeleton of the divalent group having the aromatic skeleton in Ar corresponds to Ar in an ester group-containing tetracarboxylic acid dianhydride represented by Formula (3) described later, which is used when synthesizing the resin including the aromatic polyester imide structure, and corresponds to the aromatic included in an aromatic diol among trimellitic acid anhydride chloride and the aromatic diol, which are raw materials to synthesize this ester group-containing tetracarboxylic acid dianhydride. The aromatic skeleton is a benzene skeleton, a naphthalene skeleton, a pyridine skeleton or the like, and is a divalent group which may have a hydrogen atom, or a substituent such as an alkyl group, an alkoxy group or a halogen. Specifically, it is a phenylene group or a naphthalene group, and may be an aromatic skeleton linked to another aromatic skeleton by a cross-linking group (for example, —O—, —S—, —(CO)—, —O—(CO)— or —(CO)—O—). The aromatic skeleton corresponds to the residue except for the diol of the aromatic diol described later.

The divalent group having an aromatic skeleton with 2 to 30 carbon atoms and 4 to 100 hydrogen atoms in R corresponds to a diamine residue except for amino groups of the aromatic diamine compound described later, which is used when synthesizing the resin including the aromatic polyester imide structure. Specifically, it is a phenylene group or a naphthalene group, and may be an aromatic skeleton linked to another aromatic skeleton by a cross-linking group (for example, —O—, —S—, —(CO)—, —O—(CO)— or —(CO)—O—).

The hydrocarbon group with 1 to 4 carbon atoms is a methyl group, an ethyl group, a propyl group, a butyl group, or the like.

The aliphatic hydrocarbon group with 1 to 3 carbon atoms is a methyl group, an ethyl group, a propyl group, or the like.

The resin including the aromatic polyester imide structure represented by Formula (1) is obtained by reacting the ester group-containing tetracarboxylic acid dianhydride represented by the following Formula (3) with the aromatic diamine compound. When improving the photocurability, a methacryloyl group may be introduced into a carboxylic acid generated by opening a ring of an acid anhydride. In this case, at least one of R₁, R₂, and R′ is a group represented by Formula (2).

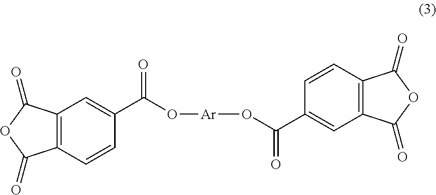

In Formula (3), Ar is a divalent group having an aromatic skeleton.

Examples of the ester group-containing tetracarboxylic acid dianhydride include bis(1,3-dioxo-1,3-dihydroisobenzofuran-5-carboxylic acid)-1,4-phenylene (p-phenylenebis(trimellitate anhydride), trade name: TAHQ, manufactured by MANAC INCORPORATED), and a product produced by reacting trimellitic acid anhydride chloride with the aromatic diol may be used.

Examples of the aromatic diol include hydroquinone, methylhydroquinone, 2,3-dimethylhydroquinone, trimethylhydroquinone, tetramethylhydroquinone, methoxyhydroquinone, 1,4-dihydroxynaphthalene, 1,7-dihydroxynaphthalene, 2,6-dihydroxynaphthalene, 4,4′-dihydroxydiphenyl ether, 1,4-bis(4-hydroxyphenoxy)benzene, 4,4′-dihydroxydiphenylmethane, 2,2′-bis(4-hydroxyphenyl)propane, resorcinol, 2-methylresorcinol, 4-methylresorcinol, 5-methylresorcinol, and 1,4-bis(3-hydroxyphenoxy)benzene. From the point of the low dielectric property, heat resistance, and availability, 1,4-dihydroxynaphthalene, 4,4′-dihydroxydiphenyl ether, 4,4′-dihydroxydiphenylmethane, 2,2′-bis(4-hydroxyphenyl)propane, and 1,4-bis(3-hydroxyphenoxy)benzene are preferable. From the point of low moisture absorption and molecular linearity, 1,4-dihydroxynaphthalene, 4,4′-dihydroxydiphenylmethane, and 2,2′-bis(4-hydroxyphenyl)propane are particularly preferable. These may be used alone or in combination of two or more.

When trimellitic acid anhydride chloride is reacted with the aromatic diol, a reaction ratio of trimellitic acid anhydride chloride is preferably from 2.0 mol to 3.0 mol with respect to 1 mol of the aromatic diol. When trimellitic acid anhydride chloride is set to 2.0 mol or more, trimellitic acid anhydride chloride is sufficiently reacted with the aromatic diol, and by setting the amount to 3.0 mol or less, it is possible that the reaction becomes less radical and the synthesis becomes stable.

The reaction for synthesizing the tetracarboxylic acid dianhydride may be performed in an organic solvent. Examples of the organic solvent include tetrahydrofuran(THF), N-methylpyrrolidone(NMP), an equamid solvent (KJCMPA-100, KJCBPA-100; all manufactured by KJ Chemicals Corporation: trade name), aprotic solvents such as pyridine, γ-butyrolactone, and dimethylacetamide(DMAc), dimethylformamide(DMF), dimethyl sulfoxide(DMSO), 1,4-dioxane, picolin, acetone, chloroform, toluene, xylene, dichloromethane, chloroform, 1,2-dichloroethane, N, N-diethylacetamide, hexamethylphosphoramide, 1,3-dimethyl-2-imidazolidinone, and 1,2-dimethoxyethane-bis(2-methoxyethyl)ether, and protic solvents such as phenol, o-cresol, m-cresol, p-cresol, o-chlorophenol, m-chlorophenol, and p-chlorophenol. Among them, from the point of solubility of a raw material, tetrahydrofuran(THF), N-methylpyrrolidone(NMP), KJCMPA-100, KJCBPA-100, dimethylacetamide(DMAc), dimethylformamide(DMF), and dimethyl sulfoxide(DMSO) are preferable, and from the point of lower toxicity, tetrahydrofuran(THF), N-methylpyrrolidone(NMP), KJCMPA-100, and KJCBPA-100 are particularly preferable. As these solvents, for example, those dehydrated with Molecular Sieves or the like are preferably used. These may be used alone or in combination of two or more.

The concentration of a solute at the time of the synthesis is preferably from 1% by mass to 50% by mass, and from the point of reaction time and reduction of a waste solvent (low environmental load), more preferably 5% by mass to 30% by mass. It is possible that when the concentration of a solute is high, the reaction temperature will become 50° C. or more and the yield reduction will occur due to a side reaction. When the internal temperature exceeds 50° C., it is preferable to cool by a method such as water cooling.

Examples of the above aromatic diamine include 1,3-bis[2-(4-aminophenyl)-2-propyl]benzene, p-phenylenediamine, m-phenylenediamine, o-phenylenediamine, 3-methyl-1,4-diaminobenzene, 2,5-dimethyl-1,4-diaminobenzene, 4,4′-diaminodiphenylmethane, 4,4′-diamino-3,3′-dimethyl-diphenylmethane, 4,4′-diamino-3,3′-diethyl-diphenylmethane, 4,4′-diaminodiphenyl ether, 3,4′-diaminodiphenyl ether, 1,3-bis(4-aminophenoxy)benzene, 4,4′-diamino-3,3′-dimethoxybiphenyl(o-dianicidine), 4,4′-diamino-2,2′-dimethylbiphenyl, 4,4′-diamino-2,2′-dimethoxybiphenyl, 4,4′-diaminodiphenylsulfone, 3,3′-diaminodiphenylsulfone, 4,4′-diaminodiphenylketone, benzidine, 3,3′-dimethyl-4,4′-diaminobiphenyl, 2,2′-dimethyl-4,4′-diaminobiphenyl, 3,3′-dihydroxybenzidine, 2,2-bis(3-amino-4-hydroxyphenyl)propane, 3,3-dimethyl-5,5-diethyl-4,4-diphenylmethanediamine, 2,2-bis(4-aminophenyl)propane, 2,2-bis(4-(4-aminophenoxy)phenyl)propane, 2,2-bis(4-(4-aminophenoxy)phenyl)hexafluoropropane, 4,4′-diamino-2,2′-bis(trifluoromethyl)diphenyl ether, 1,3-bis(3-aminophenoxy)benzene, 1,3-bis(4-aminophenoxy)benzene, 1,4-bis(4-aminophenoxy)benzene, 4,4′-bis(4-aminophenoxy)biphenyl, bis(4-(4-aminophenoxy)phenyl)sulfone, bis(4-(3-aminophenoxy)phenyl)sulfone, 9,9-bis(4-aminophenyl)fluorene, 4,4 ‘-diamino-2,2’-bis(trifluoromethyl)biphenyl, 2,2-bis(4-(4-amino-2-(trifluoromethyl)phenoxy)phenyl)hexafluoropropane, N-(4-aminophenyl)-4-aminobenzamide, and 4-aminophenyl-4-aminobenzoate. These may be used alone or in combination of two or more.

Among them, from the point of the low dielectric property, and heat resistance, p-phenylenediamine, 4,4′-diaminodiphenyl ether, 4,4′-diamino-3,3′-dimethoxybiphenyl (o-dianicidine), 4,4′-diamino-2,2′-dimethylbiphenyl, 4,4′-diamino-2,2′-bis(trifluoromethyl)biphenyl, 2,2-bis(4-(4-amino-2-(trifluoromethyl)phenoxy)phenyl)hexafluoropropane, N-(4-aminophenyl)-4-aminobenzamide, and 4-aminophenyl-4-aminobenzoate are preferable, from the point of lower toxicity, 4,4′-diaminodiphenyl ether, 4,4′-diamino-2,2′-dimethylbiphenyl, 4,4′-diamino-2,2′-bi s(trifluoromethyl)biphenyl, N-(4-aminophenyl)-4-aminobenzamide, and 4-aminophenyl-4-aminobenzoate are particularly preferable.

When a polyester imide precursor of the resin including the aromatic polyester imide structure represented by Formula (1) is synthesized, the ratio of the aromatic diamine is preferably from 0.7 to 0.99, and from the point of solubility in a solvent, particularly preferably from 0.85 to 0.97, with respect to 1 mol of the above tetracarboxylic acid dianhydride.

The reaction for synthesizing the polyester imide precursor may be performed in an organic solvent. Examples of the organic solvent include tetrahydrofuran (THF), N-methylpyrrolidone (NMP), an equamid solvent (KJCMPA-100, KJCBPA-100; all manufactured by KJ Chemicals Corporation: trade name), aprotic solvents such as pyridine, γ-butyrolactone, dimethylacetamide (DMAc), dimethylformamide (DMF), dimethylsulfoxide (DMSO), 1,4-dioxane, picolin, acetone, chloroform, toluene, xylene, dichloromethane, chloroform, 1,2-dichloroethane, N, N-diethylacetamide, hexamethylphosphoramide, 1,3-dimethyl-2-imidazolidinone, and 1,2-dimethoxyethane-bis(2-methoxyethyl)ether, and protic solvents such as phenol, o-cresol, m-cresol, p-cresol, o-chlorophenol, m-chlorophenol, and p-chlorophenol. Among them, from the point of solubility of a raw material, tetrahydrofuran (THF), N-methylpyrrolidone (NMP), KJCMPA-100, KJCBPA-100, dimethylacetamide (DMAc), dimethylformamide (DMF), and dimethyl sulfoxide (DMSO) are preferable, and from the point of lower toxicity and a high boiling point, γ-butyrolactone, N-methylpyrrolidone (NMP), KJCMPA-100, and KJCBPA-100 are particularly preferable. As these solvents, for example, those dehydrated with Molecular Sieves or the like are preferably used. These may be used alone or in combination of two or more.

The concentration of a solute at the time of the synthesis is preferably from 10% by mass to 50% by mass, and from the point of reaction time and reduction of a waste solvent (low environmental load), more preferably 15% by mass to 40% by mass. It is possible that when the concentration of a solute is high, the reaction temperature will become 50° C. or more and the yield reduction will occur due to a side reaction. When the internal temperature exceeds 50° C., it is preferable to cool by a method such as water cooling. From the point of handling, the viscosity of the polyester imide precursor solution is preferably from 0.1 dL/g to 20.0 dL/g, and particularly preferably from 0.5 dL/g to 10.0 dL/g.

After synthesizing the polyester imide precursor, a carboxylic acid generated by opening a ring of an acid anhydride may be esterified with, for example, 2-hydroxyethyl methacrylate (HEMA) to introduce a methacryloyl group. As a result, photocurability can be imparted to the polyimide polymer, and the polymer can have both the lithographic property and the low dielectric property.

(Photopolymerization Initiator)

The present disclosure may include a photopolymerization initiator. Some radical polymerization initiators are activated by light or heat, photoradical polymerization initiators (photopolymerization initiators) are not particularly limited and examples thereof preferably include benzophenone derivatives such as benzophenone, methyl o-benzoyl benzoate, 4-benzoyl-4′-methyldiphenylketone, dibenzylketone, and fluorenone; acetphenone derivatives such as 2,2′-diethoxyacetophenone, 2-hydroxy-2-methylpropiophenone, and 1-hydroxycyclohexylphenylketone; thioxanthone derivatives such as thioxanthone, 2-methylthioxanthone, 2-isopropylthioxanthone, and diethylthioxanthone; benzyl derivatives such as benzyl, benzyldimethylketal, and benzyl-β-methoxyethylacetal, benzoin derivatives such as benzoin and benzoin methyl ether; oxime esters such as 1-phenyl-1,2-butandione-2-(o-methoxycarbonyl)oxime, 1-phenyl-1,2-propanedione-2-(o-methoxycarbonyl)oxime, 1-phenyl-1,2-propanedione-2-(o-ethoxycarbonyl)oxime, 1-phenyl-1,2-propanedione-2-(o-benzoyl)oxime, 1,3-diphenylpropanthrione-2-(o-ethoxycarbonyl)oxime, 1-phenyl-3-ethoxypropanetrione-2-(o-benzoyl)oxime, etanone, 1-[9-ethyl-6-(2-methylbenzoyl)-9H-carbazole-3-yl]-, 1-(o-acetyloxime) and a compound represented by the following Formula (4). The photopolymerization initiator(s) may be used alone or in combination of two or more.

Especially, from the point of high sensitivity, the oxime esters are preferable.

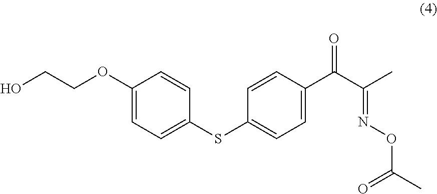 [SMILES: CC(=O)O/N=C(\C)C(=O)c1ccc(Sc2ccc(OCCO)cc2)cc1]

The content amount of the photopolymerization initiator is preferably from 0.1 parts by mass to 20 parts by mass, more preferably from 0.1 parts by mass to 10 parts by mass, and still more preferably from 0.1 parts by mass to 5 parts by mass, with respect to 100 parts by mass of the resin including the aromatic polyester imide structure represented by Formula (1).

When the content amount is within the above range, the photocrosslinking easily becomes uniform in the thickness direction of the film, and easily obtains a substantial relief pattern.

(Thermal Radical Polymerization Initiator)

As the thermal radical polymerization initiator, a compound that does not decompose by heating (drying) for removing the solvent at the time of film formation and decomposes by heating at the time of curing to generate a radical and promotes the polymerization reaction is preferable.

As the thermal radical polymerization initiator, for example, a compound with the decomposition temperature of from 110° C. to 200° C. is preferable, and from the viewpoint of promoting the polymerization reaction at lower temperature, a compound with the decomposition temperature of from 110° C. to 175° C. is more preferable.

Specific examples include ketone peroxides such as methyl ethyl ketone peroxide; peroxyketals such as 1,1-di(t-hexylperoxy)-3,3,5-trimethylcyclohexane, 1,1-di(t-hexylperoxy)cyclohexane, and 1,1-di(t-butylperoxy)cyclohexane; hydroperoxides such as 1,1,3,3-tetramethylbutylhydroperoxide, cumene hydroperoxide, and p-methane hydroperoxide; dialkyl peroxides such as dicumyl peroxide, and di-t-butyl peroxide; diacyl peroxides such as dilauroyl peroxide and dibenzoyl peroxide; peroxy dicarbonates such as di(4-t-butylcyclohexyl)peroxydicarbonate and di(2-ethylhexyl)peroxydicarbonate; peroxy esters such as t-butylperoxy-2-ethylhexanoate, t-hexylperoxyisopropyl monocarbonate, t-butylperoxybenzoate, and 1,1,3,3-tetramethylbutylperoxy-2-ethylhexanoate; and bis(1-phenyl-1-methylethyl)peroxide. Examples of commercially available products include trade names “PERCUMYL D”, “PERCUMYL P”, and “PERCUMYL H” (all manufactured by NOF CORPORATION).

The content amount of the thermal radical polymerization initiator is preferably from 0.1 parts by mass to 20 parts by mass, from the point of ensuring excellent resistance to flux, more preferably from 0.2 parts by mass to 20 parts by mass, and from the viewpoint of reducing decrease in solubility, still more preferably from 0.3 parts by mass to 10 parts by mass, with respect to 100 parts by mass of the resin including the aromatic polyester imide structure represented by Formula (1).

(Coupling Agent)

Further, the photosensitive resin composition of the present disclosure may include a coupling agent. For example, the coupling agent may be a silane coupling agent. For example, the silane coupling agent may include a vinyl group, an epoxy group, a styryl group, an acryloyl group, a methacryloyl group, an amino group, an ureido group, an isocyanate group, an isocyanurate group, a mercapto group or the like.

Examples of the silane coupling agent including a vinyl group include KBM-1003, KBE-1003 (Both are trade names, manufactured by Shin-Etsu Chemical Co., Ltd. The same applies below.) and the like.

Examples of the silane coupling agent including an epoxy group include KBM-303, 402, 403, KBE-402, 403, X-12-981S, X-12-984S and the like.

Examples of the silane coupling agent including a styryl group include KBM-1403 and the like.

Examples of the silane coupling agent including a methacryloyl group include KBM-502, 503, KBE-502, 503 and the like.

Examples of the silane coupling agent including an acryloyl group include KBM-5103, X12-1048, X-12-1050 and the like.

Examples of the silane coupling agent including an amino group include KBM-602, 603, 903, 573, 575, KBE-903, 9103P, X-12-972F and the like.

Examples of the silane coupling agent including an ureido group include KBE-585 and the like.

Examples of the silane coupling agent including an isocyanate group include KBE-9007, X-12-1159L and the like.

Examples of the silane coupling agent including an isocyanurate group include KBM-9659 and the like.

Examples of the silane coupling agent including a mercapto group include KBM-802, 803, X-12-1154, X-12-1156 and the like.

Among them, from the point of improving the adhesion by reacting with a carboxy group, it is preferable that KBM-303, 402, 403, KBE-402, 403, X-12-981S, or X-12-984S, which has an epoxy group, is used, from the point of reacting with an esterified methacryloyl group, it is preferable that KBM-502, 503, or KBE-502, 503, which has a methacryloyl group, or KBM-602, 603, 903, 573, 575, KBE-903, 9103P, or X-12-972F, which has an amino group, is used.

Among them, from the point of storage stability, KBM-502, 503, KBE-502, 503, and KBM-5103 are particularly preferable. These may be used alone or in combination of two or more depending on the purpose, application or the like.

The content amount of the silane coupling agent is, from the viewpoint of improving adhesion with glass, silica or the like, preferably from 0.01 parts by mass to 5 parts by mass, and from the viewpoint that an unreacted substance is less likely to remain, more preferably from 0.1 parts by mass to 2 parts by mass, with respect to 100 parts by mass of the resin composition.

((Meth)Acryloyl Compound)

The photosensitive resin composition of the present disclosure includes a (meth)acryloyl compound, when the resin including an aromatic polyester imide structure represented by the above Formula (1) does not include the group represented by the above Formula (2). Alternatively, when the resin including an aromatic polyester imide structure represented by Formula (1) includes the group represented by Formula (2), the photosensitive resin composition may include the (meth)acryloyl compound.

Examples of the (meth)acryloyl compound include diethylene glycol diacrylate, triethylene glycol diacrylate, tetraethylene glycol diacrylate, diethylene glycol dimethacrylate, triethylene glycol dimethacrylate, tetraethylene glycol dimethacrylate, trimethylolpropane diacrylate, trimethylolpropane triacrylate, trimethylolpropane dimethacrylate, trimethylolpropane trimethacrylate, 1,4-butanediol diacrylate, 1,6-hexanediol diacrylate, 1,4-butanediol dimethacrylate, 1,6-hexanediol dimethacrylate, pentaerythritol triacrylate, pentaerythritol tetraacrylate, pentaerythritol trimethacrylate, pentaerythritol tetramethacrylate, dipentaerythritol hexaacrylate, dipentaerythritol hexamethacrylate, styrene, divinylbenzene, 4-vinyltoluene, 4-vinylpyridine, N-vinylpyrrolidone, 2-hydroxyethyl acrylate, 2-hydroxyethyl methacrylate, 1,3-acryloyloxy-2-hydroxypropane, 1,2-methacryloyloxy-2-hydroxypropane, methylenebisacrylamide, N, N-dimethylacrylamide, N-methylolacrylamide, tris(β-hydroxyethyl)isocyanurate triacrylate, a compound represented by the following Formula (5), urethane acrylate or urethane methacrylate, urea acrylate, isocyanuric acid-modified di/triacrylate and isocyanuric acid-modified di/trimethacrylate, tricyclodecane dimethanol diacrylate (A-DCP), and tricyclodecane dimethanol methacrylate (DCP).

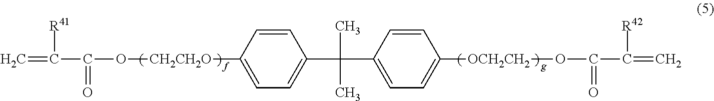

In Formula (5), each of R⁴¹ and R⁴² independently represents a hydrogen atom or a methyl group, each off and g are dependently an integer of 1 or more.

Among them from the point of good compatibility with the resin including the aromatic polyester imide structure represented by Formula (1), and being excellent in the low dielectric property, tricyclodecane dimethanol diacrylate (A-DCP), and tricyclodecane dimethanol methacrylate (DCP) are preferable.

The content amount of the (meth)acryloyl compound is preferable from 0.1 parts by mass to 30 parts by mass, and from the point of both lithography and heat resistance, particularly preferably from 0.5 parts by mass to 20 parts by mass, with respect to 100 parts by mass of the resin including the aromatic polyester imide structure represented by Formula (1).

(Other Ingredients)

The photosensitive resin composition used in the present disclosure may further include an ingredient such as a dissolution accelerator, a dissolution inhibitor, a pigment, a dye, and a surfactant or a leveling agent in addition to the above ingredients. Further, a solvent can be used to dissolve or disperse the ingredients.

(Method of Producing Patterned Cured Product)

A cured product of the present disclosure can be obtained by curing the above photosensitive resin composition.

The cured product of the present disclosure may be used as a patterned cured product or may be used as a cured product without any pattern.

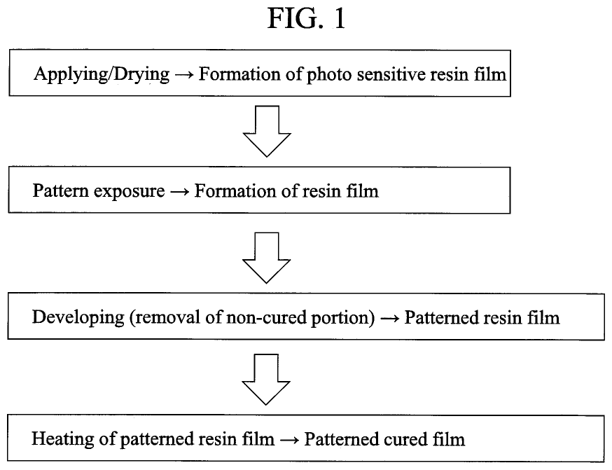

The thickness of the cured product of the present disclosure is preferably from 5 μm to 20 μm. The method of producing the patterned cured product includes a step of forming a photosensitive resin film by applying the above photosensitive resin composition to a substrate and drying the photosensitive resin composition, a step of obtaining a resin film by pattern exposure of the photosensitive resin film, a step of obtaining a patterned resin film by developing the resin film after pattern exposure, using an organic solvent, and a step of heating the patterned resin film (refer to FIG. 1).

As a result, the patterned cured product can be obtained.

The method of the cured product without any pattern includes, for example, a step of forming the above photosensitive resin film, and a step of heating it. Further, the method may include a step of developing it.

Examples of the substrate include a glass substrate, a semiconductor substrate such as a Si substrate (silicon wafer), a metal oxide insulator substrate such as a TiO₂ substrate, or SiO₂ substrate, a silicon nitride substrate, a copper substrate, a copper alloy substrate and the like.

The method of application is not particularly limited, and the application can be performed using a spinner or the like. Drying can be performed using a hot plate, oven or the like.

The temperature of drying is preferably from 90° C. to 150° C., and from the viewpoint of ensuring dissolution contrast, more preferably from 90° C. to 120° C. The time of drying is preferably from 30 seconds to 5 minutes. Drying may be performed twice or more. As a result, the photosensitive resin film in which the above photosensitive resin composition is molded into a film shape can be obtained.

The thickness of the photosensitive resin film is preferably from 5 μm to 100 μm, more preferably from 5 μm to 50 μm, and still more preferably from 5 μm to 20 μm.

A pattern exposure means that the photosensitive resin film is exposed to a predetermined pattern for example via photomask.

Examples of active rays to irradiate include i-ray, ultraviolet rays such as wide band (BB), visible light, and radiation, and i-ray is preferable.

As exposure equipment, a parallel exposure machine, a projection exposure machine, a stepper, a scanner exposure machine or the like can be used.

A pattern formed resin film (patterned resin film) can be obtained by developing.

Generally, when a negative photosensitive resin composition is used, an unexposed area is removed with a developer.

As an organic solvent used as the developer, a good solvent of the photosensitive resin film can be used alone, or a good solvent and a poor solvent can be appropriately mixed and used.

Examples of the good solvent include N-methyl-2-pyrrolidone, N-acetyl-2-pyrrolidone, N, N-dimethylacetamide, N, N-dimethylformamide, dimethyl sulfoxide, gamma-butyrolactone, α-acetyl-gamma-butyrolactone, cyclopentanone and cyclohexanone.

Examples of the poor solvent include toluene, xylene, methanol, ethanol, isopropanol, propylene glycol monomethyl ether acetate, propylene glycol monomethyl ether, and water.

Surfactant may be added to the developer. The addition amount is preferably from 0.01 parts by mass to 10 parts by mass, and more preferably from 0.1 parts by mass to 5 parts by mass, with respect to 100 parts by mass of the developer. The time of developing can be, for example, twice the time required for the photosensitive resin film to be immersed and completely dissolved. The time of developing varies depending on the component used, and is preferably from 10 seconds to 15 minutes, more preferably from 10 seconds to 5 minutes, and from the viewpoint of productivity, still more preferably from 20 seconds to 5 minutes.

After developing, it may be washed with a rinsing liquid. As the rinsing liquid, distilled water, methanol, ethanol, isopropanol, toluene, xylene, propylene glycol monomethyl ether acetate, propylene glycol monomethyl ether and the like may be used alone or in a mixed state as appropriate, or may be used in a stepwise combination.

The patterned cured product can be obtained by heating the patterned resin film. The heating temperature is preferably 250° C. or less, more preferably from 120° C. to 250° C., and still more preferably 200° C. or less or from 140° C. to 200° C.

Within the above range, damage to the substrate or the device can be reduced to a small extent, the device can be produced at a high yield, and energy saving of the process can be realized.

The heating time is preferably 5 hours or less, and more preferably from 3 minutes to 3 hours.

The heating atmosphere may be an air atmosphere or an inert atmosphere such as nitrogen, and from the viewpoint of preventing oxidation of the patterned resin film, a nitrogen atmosphere is preferable. Examples of the apparatus used for the heat treatment include a quartz tube furnace, a hot plate, a rapid thermal annealing, a vertical diffusion furnace, an infrared curing furnace, an electron beam curing furnace, a microwave curing furnace, and the like.

The cured product of the present disclosure can be used as a passivation film, a buffer coat film, an interlayer insulating film, a cover coat layer, a surface protective film, or the like.

It is possible to produce highly reliable electronic components such as semiconductor devices, multilayer wiring boards, various electronic devices, and laminated devices (multi-die fan-out wafer-level packages, or the like) by using one or more selected by the group consisting of the passivation film, the buffer coat film, the interlayer insulating film, the cover coat layer, the surface protective film, and the like.

In a cured product of the photosensitive resin composition of the present disclosure, the chloride ion concentration is preferably 5 ppm or less. When the chloride ion concentration is 5 ppm or less, electrolytic corrosion can be prevented and moisture resistance improves in the semiconductor device of the electronic component.

The breaking elongation of the cured product is preferably from 10% to 200%. It is possible to relieve the stress of the electronic component and improve reliability.

When the dielectric constant at 10 GHz is 3.2 or less or the dissipation factor is 0.0100 or less in the cured product, the low dielectric property is excellent, and the dielectric loss and transmission loss can be reduced even in a high frequency region such as 5G.

When the weight reduction temperature by 5% is 300° C. or more in a cured product, heat resistance is excellent, and when the coefficient of moisture absorption after being left in an environment of 130° C. and 85% relative humidity for 200 hours is 1% by mass or less in a cured product, moisture absorption is reduced and electrical and mechanical properties are improved.

When the heating temperature is 200° C. or less, damage to the substrate or the device can be reduced to a small extent, the device can be produced at a high yield.

(Electronic Component)

An example of a producing step of a semiconductor device which is the electronic component of the present disclosure will be described with reference to the drawing.

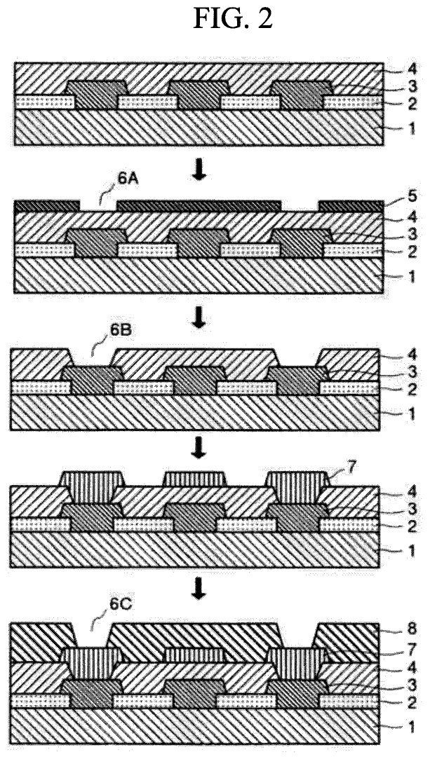

FIG. 2 is a drawing showing a step of producing the semiconductor device with multilayer wiring structure, which is the electronic component according to one embodiment of the present disclosure.

In FIG. 2, a semiconductor substrate 1 such as a Si substrate with a circuit element is covered with a protective film 2 such as a silicon oxide film except for a predetermined portion of the circuit element, a first conductive layer is formed on the exposed circuit element. Then, an interlayer insulating film 4 is formed on the above semiconductor substrate 1.

Next, a photosensitive resin layer 5 such as a chlorinated rubber type or a phenol novolak type is formed on the interlayer insulating film 4, and a window 6A is provided so that a predetermined portion of the interlayer insulating film 4 is exposed by a known photo-etching technique.

The interlayer insulating film 4, in which the window 6A is exposed, is selectively etched to provide a window 6B.

Next, the photosensitive resin layer 5 is completely removed by using an etching solution that corrodes only the photosensitive resin layer 5 without corroding the first conductive layer 3 exposed from the window 6B.

Further, using a known photo-etching technique, a second conductive layer 7 is formed and electrically connected to the first conductive layer 3.

When forming a multilayer wiring structure with three or more layers, the above steps can be repeated to form each of the layers.

Next, using the above-mentioned photosensitive resin composition, a window 6C is opened by pattern exposure to form a surface protective film 8. The surface protective film 8 protects the second conductive layer 7 from external stress, a rays, or the like, and the obtained semiconductor device is excellent in reliability.

In the above example, it is also possible to form the interlayer insulating film by using the photosensitive resin composition of the present disclosure.

### EXAMPLES

Hereinafter, the present disclosure will be further specifically described based on Examples and Comparative Examples. The present disclosure is not limited to the following Examples.

Each component used in Examples of the present disclosure is as follows.

1. Acid Anhydride

[1] p-Phenylenebis(trimellitate anhydride) (TAHQ, manufactured by MANAC INCORPORATED: trade name)
[2] Acid anhydride (1) (self-synthesized, production example 1 below)
[3] Acid anhydride (2) (self-synthesized, production example 2 below)
[4] Acid anhydride (3) (self-synthesized, production example 3 below)
[5] Piromellitic acid anhydride
[6] 1,6-(Hexamethylene)bis(trimellitate anhydride)

2. Aromatic Diol

### [1] 1,4-Dihydroxynaphthalene

### [2] 4,4′-Dihydroxydiphenylmethane

[3] 2,2′-Bis(4-hydroxyphenyl)propane

3. Aromatic Diamine

[1] p-Phenylenediamine
[2] 4,4′-Diaminodiphenyl ether

### [3] 4,4′-Diamino-2,2′-bis(trifluoromethyl)biphenyl

[4] 4-Aminophenyl-4-aminobenzoate
[5] 4,4′-Diamino-2,2′-dimethylbiphenyl

4. Coupling Agent

[1] KBM-503 (3) (3-methacryloxypropyltrimethoxysilane, manufactured by Shin-Etsu Chemical Co., Ltd.: Trade name)

5. (Meth)Acryloyl Compound

[1] Tricyclodecane dimethanol diacrylate (A-DCP, manufactured by SHIN-NAKAMURA CHEMICAL Co., Ltd.: Trade name)

6. Photopolymerization Initiator and Thermal Radical Polymerization Initiator

[1] Dicumyl peroxide (PERCUMYL D, manufactured by NOF CORPORATION: trade name)
[2] 1-[9-ethyl-6-(2-methylbenzoyl)-9H-carbazoyl-3-yl]etanone-1-(o-acetyloxime) (OXE02, manufactured by BASF SE: trade name)

7. Solvent

[1] NMP (N-methyl-2-pyrrolidone)

Aromatic polyester precursors (1) to (16) and aromatic polyimide (1) to (3) were synthesized by the following production examples 1 to 22 and were used in Examples.

Using the resin synthesized above, “OXE02” as the photopolymerization initiator, and “PERCUMYL D” as the thermal radical polymerization initiator, resin compositions of Examples 1 to 16 and Comparative Examples 1 to 6 shown in Tables 1 to 3 below were prepared and used for the tests.

### Production Example 1

### <Synthesis of Acid Anhydride (1)>

The tetracarboxylic acid dianhydride (referred to as acid anhydride (1)) including aromatic ester skeletons, which is shown in Formula (6), was synthesized as shown below.

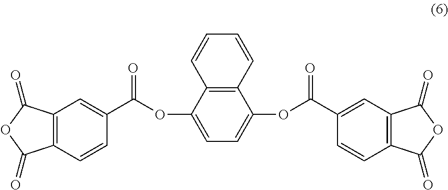 [SMILES: O=C(Oc1ccc(OC(=O)c2ccc3c(c2)C(=O)OC3=O)c2ccccc12)c1ccc2c(c1)C(=O)OC2=O]

In an eggplant flask, trimellitic acid anhydride chloride (48 mmol) was dissolved in dehydrated tetrahydrofuran (THF) (45.5 mL) and sealed with a septum cap to prepare Solution A. In another flask, 1,4-dihydroxynaphthalene (20 mmol) was dissolved in THF (68.5 mL), pyridine (120 mmol) was added thereto, and the flask was sealed with a septum cap to prepare Solution B.

While cooling and stirring the solution A in an ice bath, the solution B was slowly added dropwise to the solution A with a syringe, and then the mixture was stirred at room temperature (25° C.) for 12 hours. After completion of the reaction, the white precipitate (pyridine hydrochloride) was filtered off, the filtrate was concentrated by an evaporator, dropped into water, the precipitated precipitate was repeatedly washed with water, and vacuum dried at 160° C. for 12 hours, to obtain a yellow powdery crude product. This product was recrystallized with acetic anhydride, washed with acetic anhydride and toluene, and vacuum dried at 160° C. for 12 hours to obtain a yellow crystalline acid anhydride (1).

### Production Example 2

### <Synthesis of Acid Anhydride (2)>

The tetracarboxylic acid dianhydride (referred to as acid anhydride (2)) including aromatic ester skeletons, which is shown in Formula (7), was synthesized as shown below.

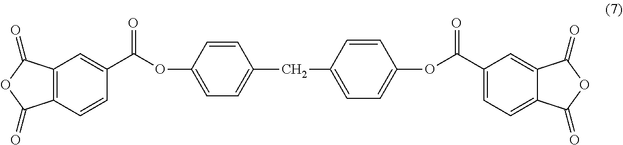 [SMILES: O=C(Oc1ccc(Cc2ccc(OC(=O)c3ccc4c(c3)C(=O)OC4=O)cc2)cc1)c1ccc2c(c1)C(=O)OC2=O]

In an eggplant flask, trimellitic acid anhydride chloride (48 mmol) was dissolved in dehydrated tetrahydrofuran (THF) (45.5 mL) and sealed with a septum cap to prepare Solution A. In another flask, 4,4-dihydroxydiphenylmethane (20 mmol) was dissolved in THF (68.5 mL), pyridine (120 mmol) was added thereto, and the flask was sealed with a septum cap to prepare Solution B.

While cooling and stirring the solution A in an ice bath, the solution B was slowly added dropwise to the solution A with a syringe, and then the mixture was stirred at room temperature for 12 hours. After completion of the reaction, the white precipitate (pyridine hydrochloride) was filtered off, the filtrate was concentrated by an evaporator, dropped into water, the precipitated precipitate was repeatedly washed with water, and vacuum dried at 160° C. for 12 hours, to obtain a yellow powdery crude product. This product was recrystallized with acetic anhydride, washed with acetic anhydride and toluene, and vacuum dried at 160° C. for 12 hours to obtain a yellow crystalline acid anhydride (2).

### Production Example 3

### <Synthesis of Acid Anhydride (3)>

The tetracarboxylic acid dianhydride (referred to as acid anhydride (3)) including aromatic ester skeletons, which is shown in Formula (8), was synthesized as shown below.

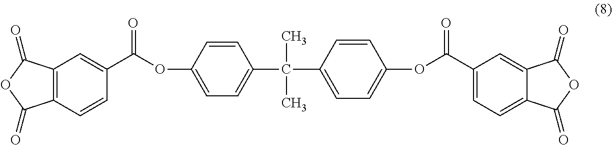 [SMILES: CC(C)(c1ccc(OC(=O)c2ccc3c(c2)C(=O)OC3=O)cc1)c1ccc(OC(=O)c2ccc3c(c2)C(=O)OC3=O)cc1]

In an eggplant flask, trimellitic acid anhydride chloride (48 mmol) was dissolved in dehydrated tetrahydrofuran (THF) (45.5 mL) and sealed with a septum cap to prepare Solution A. In another flask, 2,2′-bis(4-hydroxyphenyl)propane (20 mmol) was dissolved in THF (68.5 mL), pyridine (120 mmol) was added thereto, and the flask was sealed with a septum cap to prepare Solution B.

While cooling and stirring the solution A in an ice bath, the solution B was slowly added dropwise to the solution A with a syringe, and then the mixture was stirred at room temperature for 12 hours. After completion of the reaction, the white precipitate (pyridine hydrochloride) was filtered off, the filtrate was concentrated by an evaporator, dropped into water, the precipitated precipitate was repeatedly washed with water, and vacuum dried at 160° C. for 12 hours, to obtain a yellow powdery crude product. This product was recrystallized with acetic anhydride, washed with acetic anhydride and toluene, and vacuum dried at 160° C. for 12 hours to obtain a yellow crystalline acid anhydride (3).

### Production Example 4

### <Synthesis of Aromatic Polyester Imide Precursor (1)>

p-Phenylenediamine (4.75 mol) was put in a flask dried at 60° C. for 1 hour, and it was dissolved in ultra-dehydrated N-methyl-2-pyrrolidone (NMP). Then, p-phenylenebis(trimellitate anhydride) (TAHQ, 5 mol) dried at 180° C. for 5 hours was added little by little while stirring the solution. Then, the mixture was stirred at uncontrolled room temperature of 20 to 30° C. for 24 hours to obtain a solution of an aromatic ester imide precursor (1). (non-volatile component of varnish of 25% by mass).

### Production Example 5

### <Synthesis of Aromatic Polyester Imide Precursor (2)>

Trifluoroacetic anhydride (9.87 mol) was added to the solution of the aromatic polyester imide precursor (1) prepared above under water cooling, and the mixture was stirred at 45° C. for 3 hours, and 2-hydroxyethyl methacrylate (HEMA) (7.4 mol) was added thereto. This reaction solution was added dropwise to distilled water, and the precipitate was collected by filtration and dried under reduced pressure. The obtained powder was dissolved in ultra-dehydrated NMP to obtain a solution of an aromatic polyester imide precursor (2) (non-volatile component of 25% by mass).

### Production Example 6

### <Synthesis of Aromatic Polyester Imide Precursor (3)>

4,4′-diaminodiphenyl ether (4.75 mol) was put in a flask dried at 60° C. for 1 hour, and it was dissolved in ultra-dehydrated N-methyl-2-pyrrolidone (NMP). Then, p-phenylenebis(trimellitate anhydride) (TAHQ, 5 mol) dried at 180° C. for 5 hours was added little by little while stirring the solution. Then, the mixture was stirred at uncontrolled room temperature of 20 to 30° C. for 24 hours to obtain a solution of an aromatic ester imide precursor (3). (non-volatile component of varnish of 25% by mass).

### Production Example 7

### <Synthesis of Aromatic Polyester Imide Precursor (4)>

Trifluoroacetic anhydride (9.87 mol) was added to the solution of the aromatic polyester imide precursor (3) prepared above under water cooling, and the mixture was stirred at 45° C. for 3 hours, and 2-hydroxyethyl methacrylate (HEMA) (7.4 mol) was added thereto. This reaction solution was added dropwise to distilled water, and the precipitate was collected by filtration and dried under reduced pressure. The obtained powder was dissolved in ultra-dehydrated NMP to obtain a solution of an aromatic polyester imide precursor (4) (non-volatile component of 25% by mass).

### Production Example 8

### <Synthesis of Aromatic Polyester Imide Precursor (5)>

4,4′-diamino-2,2′-bis(trifluoromethyl)biphenyl (4.75 mol) was put in a flask dried at 60° C. for 1 hour, and it was dissolved in ultra-dehydrated N-methyl-2-pyrrolidone (NMP). Then, p-phenylenebis(trimellitate anhydride) (TAHQ, 5 mol) dried at 180° C. for 5 hours was added little by little while stirring the solution. Then, the mixture was stirred at uncontrolled room temperature of 20 to 30° C. for 24 hours to obtain a solution of an aromatic ester imide precursor (5). (non-volatile component of varnish of 25% by mass).

### Production Example 9

### <Synthesis of Aromatic Polyester Imide Precursor (6)>

Trifluoroacetic anhydride (9.87 mol) was added to the solution of the aromatic polyester imide precursor (5) prepared above under water cooling, and the mixture was stirred at 45° C. for 3 hours, and 2-hydroxyethyl methacrylate (HEMA) (7.4 mol) was added thereto. This reaction solution was added dropwise to distilled water, and the precipitate was collected by filtration and dried under reduced pressure. The obtained powder was dissolved in ultra-dehydrated NMP to obtain a solution of an aromatic polyester imide precursor (6) (non-volatile component of 25% by mass).

### Production Example 10

### <Synthesis of Aromatic Polyester Imide Precursor (7)>

4-aminophenyl-4-aminobenzoate (4.75 mol) was put in a flask dried at 60° C. for 1 hour, and it was dissolved in ultra-dehydrated N-methyl-2-pyrrolidone (NMP). Then, p-phenylenebis(trimellitate anhydride) (TAHQ, 5 mol) dried at 180° C. for 5 hours was added little by little while stirring the solution. Then, the mixture was stirred at uncontrolled room temperature of 20 to 30° C. for 24 hours to obtain a solution of an aromatic ester imide precursor (7). (non-volatile component of varnish of 25% by mass).

### Production Example 11

### <Synthesis of Aromatic Polyester Imide Precursor (8)>

Trifluoroacetic anhydride (9.87 mol) was added to the solution of the aromatic polyester imide precursor (7) prepared above under water cooling, and the mixture was stirred at 45° C. for 3 hours, and 2-hydroxyethyl methacrylate (HEMA) (7.4 mol) was added thereto. This reaction solution was added dropwise to distilled water, and the precipitate was collected by filtration and dried under reduced pressure. The obtained powder was dissolved in ultra-dehydrated NMP to obtain a solution of an aromatic polyester imide precursor (8) (non-volatile component of 25% by mass).

### Production Example 12

### <Synthesis of Aromatic Polyester Imide Precursor (9)>

4,4′-diamino-2,2′-dimethylbiphenyl (4.75 mol) was put in a flask dried at 60° C. for 1 hour, and it was dissolved in ultra-dehydrated N-methyl-2-pyrrolidone (NMP). Then, p-phenylenebis(trimellitate anhydride) (TAHQ, 5 mol) dried at 180° C. for 5 hours was added little by little while stirring the solution. Then, the mixture was stirred at uncontrolled room temperature of 20 to 30° C. for 24 hours to obtain a solution of an aromatic ester imide precursor (9). (non-volatile component of varnish of 25% by mass).

### Production Example 13

### <Synthesis of Aromatic Polyester Imide Precursor (10)>

Trifluoroacetic anhydride (9.87 mol) was added to the solution of the aromatic polyester imide precursor (9) prepared above under water cooling, and the mixture was stirred at 45° C. for 3 hours, and 2-hydroxyethyl methacrylate (HEMA) (7.4 mol) was added thereto. This reaction solution was added dropwise to distilled water, and the precipitate was collected by filtration and dried under reduced pressure. The obtained powder was dissolved in ultra-dehydrated NMP to obtain a solution of an aromatic polyester imide precursor (10) (non-volatile component of 25% by mass).

### Production Example 14

### <Synthesis of Aromatic Polyester Imide Precursor (11)>

p-Phenylenediamine(4.75 mol) was put in a flask dried at 60° C. for 1 hour, and it was dissolved in ultra-dehydrated N-methyl-2-pyrrolidone (NMP). Then, the acid anhydride (2) (5 mol) dried at 180° C. for 5 hours was added little by little while stirring the solution. Then, the mixture was stirred at uncontrolled room temperature of 20 to 30° C. for 24 hours to obtain a solution of an aromatic ester imide precursor (11). (non-volatile component of varnish of 25% by mass).

### Production Example 15

### <Synthesis of Aromatic Polyester Imide Precursor (12)>

Trifluoroacetic anhydride (9.87 mol) was added to the solution of the aromatic polyester imide precursor (11) prepared above under water cooling, and the mixture was stirred at 45° C. for 3 hours, and 2-hydroxyethyl methacrylate (HEMA) (7.4 mol) was added thereto. This reaction solution was added dropwise to distilled water, and the precipitate was collected by filtration and dried under reduced pressure. The obtained powder was dissolved in ultra-dehydrated NMP to obtain a solution of an aromatic polyester imide precursor (12) (non-volatile component of 25% by mass).

### Production Example 16

### <Synthesis of Aromatic Polyester Imide Precursor (13)>

p-Phenylenediamine(4.75 mol) was put in a flask dried at 60° C. for 1 hour, and it was dissolved in ultra-dehydrated N-methyl-2-pyrrolidone (NMP). Then, the acid anhydride (2) (5 mol) dried at 180° C. for 5 hours was added little by little while stirring the solution. Then, the mixture was stirred at uncontrolled room temperature of 20 to 30° C. for 24 hours to obtain a solution of an aromatic ester imide precursor (13). (non-volatile component of varnish of 25% by mass).

### Production Example 17

### <Synthesis of Aromatic Polyester Imide Precursor (14)>

Trifluoroacetic anhydride (9.87 mol) was added to the solution of the aromatic polyester imide precursor (13) prepared above under water cooling, and the mixture was stirred at 45° C. for 3 hours, and 2-hydroxyethyl methacrylate (HEMA) (7.4 mol) was added thereto. This reaction solution was added dropwise to distilled water, and the precipitate was collected by filtration and dried under reduced pressure. The obtained powder was dissolved in ultra-dehydrated NMP to obtain a solution of an aromatic polyester imide precursor (14) (non-volatile component of 25% by mass).

### Production Example 18

### <Synthesis of Aromatic Polyester Imide Precursor (15)>

p-Phenylenediamine(4.75 mol) was put in a flask dried at 60° C. for 1 hour, and it was dissolved in ultra-dehydrated N-methyl-2-pyrrolidone (NMP). Then, the acid anhydride (3) (5 mol) dried at 180° C. for 5 hours was added little by little while stirring the solution. Then, the mixture was stirred at uncontrolled room temperature of 20 to 30° C. for 24 hours to obtain a solution of an aromatic ester imide precursor (15). (non-volatile component of varnish of 25% by mass).

### Production Example 19

### <Synthesis of Aromatic Polyester Imide Precursor (16)>

Trifluoroacetic anhydride (9.87 mol) was added to the solution of the aromatic polyester imide precursor (15) prepared above under water cooling, and the mixture was stirred at 45° C. for 3 hours, and 2-hydroxyethyl methacrylate (HEMA) (7.4 mol) was added thereto. This reaction solution was added dropwise to distilled water, and the precipitate was collected by filtration and dried under reduced pressure. The obtained powder was dissolved in ultra-dehydrated NMP to obtain a solution of an aromatic polyester imide precursor (16) (non-volatile component of 25% by mass).

### Production Example 20

### <Synthesis of Aromatic Polyimide (1)>

p-Phenylenediamine(4.75 mol) was put in a flask dried at 60° C. for 1 hour, and it was dissolved in ultra-dehydrated N-methyl-2-pyrrolidone (NMP). Then, piromellitic anhydride (5 mol) dried at 180° C. for 5 hours was added little by little while stirring the solution. Then, the mixture was stirred at uncontrolled room temperature of 20 to 30° C. for 24 hours to obtain a solution of an aromatic imide precursor (1). (non-volatile component of varnish of 25% by mass).

### Production Example 21

### <Synthesis of Aromatic Polyimide (2)>

p-Phenylenediamine(4.75 mol) was put in a flask dried at 60° C. for 1 hour, and it was dissolved in ultra-dehydrated N-methyl-2-pyrrolidone (NMP). Then, 3,3′, 4,4′-diphenyl ether tetracarboxylic acid dianhydride (5 mol) dried at 180° C. for 5 hours was added little by little while stirring the solution. Then, the mixture was stirred at uncontrolled room temperature of 20 to 30° C. for 24 hours to obtain a solution of an aromatic imide precursor (2). (non-volatile component of varnish of 25% by mass).

### Production Example 22

### <Synthesis of Aromatic Polyimide (3)>

4,4′-diaminodiphenyl ether (4.75 mol) was put in a flask dried at 60° C. for 1 hour, and it was dissolved in ultra-dehydrated N-methyl-2-pyrrolidone (NMP). Then, 3,3′, 4,4′-diphenyl ether tetracarboxylic acid dianhydride (5 mol) dried at 180° C. for 5 hours was added little by little while stirring the solution. Then, the mixture was stirred at uncontrolled room temperature of 20 to 30° C. for 24 hours to obtain a solution of an aromatic imide precursor (3). (non-volatile component of varnish of 25% by mass).

<Method of Producing Evaluation Sample>

First Titanium (Ti) of 50 nm was spattered and then copper (Cu) of 250 nm was spattered on a silicon wafer, and the obtained wafer was electrolytically plated with copper to prepare a substrate in which copper was grown to a thickness of 20 Then, each of the photosensitive resin composition varnishes with Formulations of Examples 1 to 16 and Comparative Examples 1 to 6 shown in Tables 1 to 3 was applied onto the above substrate with a spin coater, and the solvent was volatilized by prebaking. Next, UV light of 500 mJ/cm² was irradiated. After cutting out to the size required for evaluating the physical properties with a cutter, each of the evaluation samples in Examples 1 to 16 was cured at 200° C., and each of the evaluation samples in Comparative Examples 1 to 6 were cured at 250° C. for 2 hours in an N₂ oven. The condition at the time of film formation was adjusted so that the thickness of each film was set to be 10 μm after full curing. Finally, the copper portion was etched and washed with water by immersing it in an aqueous solution of ammonium peroxodisulfate having the concentration of 50% by mass to obtain a resin sample.

<Evaluation of Evaluation Sample>

### <Measurement of Chloride Ion Concentration>

For the measurement of chloride ion concentration, an extract from a cured product of a photosensitive resin composition was used, and “Device name: ICS-2000”, “detector: electrical conductivity detector” and “column: AS20 (diameter 4 mm×200 mm)” manufactured by Dionex Corporation analysis was performed under the conditions of 30° C., 1.0 ml/min, and an injection volume of 25 μl.

<Measurement of Breaking Elongation>

In the production of the above evaluation sample, a film was formed in the same manner up to the point where the solvent was volatilized by prebaking. Next, in the time of the exposure, the exposure was performed through a mask having a length of 30 mm and a width of 5 mm. The obtained sample was developed and cured, and the copper portion was etched and washed with water by immersing it in the aqueous solution of ammonium peroxodisulfate having the concentration of 50% by mass in the same manner as described above to obtain a resin sample. Using the obtained sample, the breaking elongation was measured when measured at a feed rate (pulling speed) of 5 mm/min with a small tabletop tester (manufactured by Shimadzu Corporation, trade name: EZ-S).

<Dielectric Properties (Relative Dielectric Constant and Dissipation Factor)>

Dielectric properties (dielectric constant Dk and dissipation factor Df) were measured by the SPDR method using an evaluation sample cut out to a predetermined size. An SPDR dielectric resonator manufactured by Agilent Technologies was used for the SPDR, and a vector network analyzer E8364B manufactured by Agilent Technologies was used for the measuring instrument, and CPMA-V2 was used for the measuring program. The conditions were a frequency of 10 GHz and a measurement temperature of 25° C.

<Measurements of Weight Reduction Temperature by 5% and Coefficient of Moisture Absorption>

The produced sample was placed in a temperature and humidity testing chamber (manufactured by ESPEC CORP., trade name: EHS-221MD) set at a relative humidity of 85% and 130° C. for 200 hours. Then, after the temperature in the temperature and humidity testing chamber was lowered to 50° C., the sample was taken out, and a part of the resin was measured with a differential thermogravimetric simultaneous analyzer (manufactured by Hitachi High-Tech Science Corporation, trade name: TG/DTA6300) under the conditions of a heating rate of 10° C./min, a nitrogen flow of 400 mL/min, and a temperature range of 25° C. to 150° C. On the other hand, the similarly produced sample was dried at 130° C. for 2 hours, and TG-DTA was measured by the same method. The difference in the weight reduction rate at 150° C. was calculated as the coefficient of moisture absorption.

<Evaluation of Pattern Formability>

The produced varnish was applied on a silicon wafer with a spin coater, and the solvent was volatilized by prebaking. Next, during the exposure, the exposure was performed through a negative mask having Line/Space of 10 μm/10 μm. The obtained sample was developed, and the pattern formability was evaluated by judging that the one without any appearance defect such as film peeling and swelling/collapse of the pattern was A and the one with the appearance defect was B.

The above measurement and evaluation results are summarized in Tables 1 to 3.

TABLE 1

| Items | | Example 1 | Example 2 | Example 3 | Example 4 | Example 5 | Example 6 | Example 7 | Example 8 |
|---|---|---|---|---|---|---|---|---|---|
| Aromatic | (1) | 100 | — | — | — | — | — | — | — |
| polyester imide | (3) | — | 100 | — | — | — | — | — | — |
| | (5) | — | — | 100 | — | — | — | — | — |
| | (7) | — | — | — | 100 | — | — | — | — |
| | (9) | — | — | — | — | 100 | — | — | — |
| | (11) | — | — | — | — | — | 100 | — | — |
| | (13) | — | — | — | — | — | — | 100 | — |
| | (15) | — | — | — | — | — | — | — | 100 |
| | (2) | — | — | — | — | — | — | — | — |
| | (4) | — | — | — | — | — | — | — | — |
| | (6) | — | — | — | — | — | — | — | — |
| | (8) | — | — | — | — | — | — | — | — |
| | (10) | — | — | — | — | — | — | — | — |
| | (12) | — | — | — | — | — | — | — | — |
| | (14) | — | — | — | — | — | — | — | — |
| | (16) | — | — | — | — | — | — | — | — |
| Aromatic | (1) | — | — | — | — | — | — | — | — |
| polyimide | (2) | — | — | — | — | — | — | — | — |
| | (3) | — | — | — | — | — | — | — | — |
| Coupling agent | KBM-503 | 0.3 | 0.3 | 0.3 | 0.3 | 0.3 | 0.3 | 0.3 | 0.3 |
| (Meth)acryloyl | A-DCP | 10 | 10 | 10 | 10 | 10 | 10 | 10 | 10 |
| compound | | | | | | | | | |
| Radical | PERCUMYL | 2 | 2 | 2 | 2 | 2 | 2 | 2 | 2 |
| polymerization | D | | | | | | | | |
| initiator | OXE02 | 0.2 | 0.2 | 0.2 | 0.2 | 0.2 | 0.2 | 0.2 | 0.2 |

| | | | | | | | | |
|---|---|---|---|---|---|---|---|---|
| Chloride ion concentration | <1 | <1 | <1 | <1 | <1 | <1 | <1 | <1 |
| (ppm) | | | | | | | | |
| Breaking elongation (%) | 60 | 120 | 100 | 120 | 120 | 100 | 120 | 120 |
| Dielectric constant Dk@ | 2.8 | 3.0 | 2.8 | 2.8 | 2.8 | 3.0 | 2.8 | 2.8 |
| 10 GHZ | | | | | | | | |
| Dissipation factor Df@ | 0.0020 | 0.0035 | 0.0025 | 0.0025 | 0.0040 | 0.0025 | 0.0030 | 0.0025 |
| 10 GHz | | | | | | | | |
| Weight reduction temperature | 420 | 400 | 390 | 400 | 380 | 410 | 400 | 400 |
| by 5% (° C.) | | | | | | | | |
| Coefficient of moisture | 0.4 | 0.5 | 0.3 | 0.2 | 0.5 | 0.3 | 0.3 | 0.2 |
| absorption (%) | | | | | | | | |
| Pattern formability | A | A | A | A | A | A | A | A |

TABLE 2

| Items | | Example 9 | Example 10 | Example 11 | Example 12 | Example 13 | Example 14 | Example 15 | Example 16 |
|---|---|---|---|---|---|---|---|---|---|
| Aromatic polyester | (1) | — | — | — | — | — | — | — | — |
| imide | (3) | — | — | — | — | — | — | — | — |
| | (5) | — | — | — | — | — | — | — | — |
| | (7) | — | — | — | — | — | — | — | — |
| | (9) | — | — | — | — | — | — | — | — |
| | (11) | — | — | — | — | — | — | — | — |
| | (13) | — | — | — | — | — | — | — | — |
| | (15) | — | — | — | — | — | — | — | — |
| | (2) | 100 | — | — | — | — | — | — | — |
| | (4) | — | 100 | — | — | — | — | — | — |
| | (6) | — | — | 100 | — | — | — | — | — |
| | (8) | — | — | — | 100 | — | — | — | — |
| | (10) | — | — | — | — | 100 | — | — | — |
| | (12) | — | — | — | — | — | 100 | — | — |
| | (14) | — | — | — | — | — | — | 100 | — |
| | (16) | — | — | — | — | — | — | — | 100 |
| Aromatic polyimide | (1) | — | — | — | — | — | — | — | — |
| | (2) | — | — | — | — | — | — | — | — |
| | (3) | — | — | — | — | — | — | — | — |
| Coupling agent | KBM-503 | 0.3 | 0.3 | 0.3 | 0.3 | 0.3 | 0.3 | 0.3 | 0.3 |
| (Meth)acryloyl | A-DCP | — | — | — | — | — | — | — | — |
| compound | | | | | | | | | |
| Radical | PERCUMYL | 2 | 2 | 2 | 2 | 2 | 2 | 2 | 2 |
| polymerization | D | | | | | | | | |
| initiator | OXE02 | 0.2 | 0.2 | 0.2 | 0.2 | 0.2 | 0.2 | 0.2 | 0.2 |

| | | | | | | | | |
|---|---|---|---|---|---|---|---|---|
| Chloride ion concentration (ppm) | <1 | <1 | <1 | <1 | <1 | <1 | <1 | <1 |
| Breaking elongation (%) | 80 | 140 | 120 | 140 | 140 | 120 | 140 | 140 |
| Dielectric constant Dk@ 10 GHZ | 2.6 | 2.8 | 2.6 | 2.6 | 2.6 | 2.8 | 2.6 | 2.6 |
| Dissipation factor Df@ 10 GHz | 0.0015 | 0.0030 | 0.0020 | 0.0020 | 0.0035 | 0.0020 | 0.0025 | 0.0020 |
| Weight reduction temperature by | 430 | 420 | 410 | 430 | 420 | 420 | 410 | 410 |
| 5% (° C.) | | | | | | | | |
| Coefficient of moisture absorption | 0.5 | 0.6 | 0.4 | 0.2 | 0.5 | 0.4 | 0.4 | 0.3 |
| (%) | | | | | | | | |
| Pattern formability | A | A | A | A | A | A | A | A |

TABLE 3

| | | Comparative | Comparative | Comparative | Comparative | Comparative | Comparative |
|---|---|---|---|---|---|---|---|
| Items | | Example 1 | Example 2 | Example 3 | Example 4 | Example 5 | Example 6 |
| Aromatic polyester imide | (1) | — | — | — | — | — | — |
| | (3) | — | — | — | — | — | — |
| | (5) | — | — | — | — | — | — |
| | (7) | — | — | — | — | — | — |
| | (9) | — | — | — | — | — | — |
| | (11) | — | — | — | — | — | — |
| | (13) | — | — | — | — | — | — |
| | (15) | — | — | — | — | — | — |
| | (2) | — | — | — | — | — | — |
| | (4) | — | — | — | — | — | — |
| | (6) | — | — | — | — | — | — |
| | (8) | — | — | — | — | — | — |
| | (10) | — | — | — | — | — | — |
| | (12) | — | — | — | — | — | — |
| | (14) | — | — | — | — | — | — |
| | (16) | — | — | — | — | — | — |
| Aromatic polyimide | (1) | 100 | — | — | 100 | — | — |
| | (2) | — | 100 | — | — | 100 | — |
| | (3) | — | — | 100 | — | — | 100 |
| Coupling agent | KBM-503 | 0.3 | 0.3 | 0.3 | 0.3 | 0.3 | 0.3 |
| (Meth)acryloyl compound | A-DCP | 10 | 10 | 10 | — | — | — |
| Radical polymerization | PERCUMYL | 2 | 2 | 2 | 2 | 2 | 2 |
| initiator | D | | | | | | |
| | OXE02 | 0.2 | 0.2 | 0.2 | 0.2 | 0.2 | 0.2 |

| | | | | | | |
|---|---|---|---|---|---|---|
| Chloride ion concentration (ppm) | <1 | <1 | <1 | <1 | <1 | <1 |
| Breaking elongation (%) | 25 | 30 | 40 | 30 | 40 | 50 |
| Dielectric constant Dk@ 10 GHZ | 3.3 | 3.3 | 3.3 | 3.5 | 3.5 | 3.5 |
| Dissipation factor Df@ 10 GHz | 0.0220 | 0.0260 | 0.0260 | 0.0200 | 0.0250 | 0.0250 |
| Weight reduction temperature by 5% (° C.) | 380 | 390 | 400 | 430 | 410 | 400 |
| Coefficient of moisture absorption (%) | 2.0 | 2.0 | 2.0 | 2.0 | 2.0 | 2.0 |
| Pattern formability | B | B | B | A | A | A |

When the aromatic polyimide resins of Comparative Examples 1 to 6 were used, the pattern formability deteriorates when used in combination with the (meth)acryloyl compound. The breaking elongation was as low as 25% to 50%, the coefficient of moisture absorption was as high as 2%, and further the values of the dielectric constant and the dissipation factor were high and the dielectric properties were inferior.

On the other hand, the photosensitive resin composition using the resin including the aromatic polyester imide structure represented by Formula (1) of the present disclosure shown in Examples 1 to 16 had excellent pattern formability and the breaking elongation was as high as 60% to 140%, the coefficient of moisture absorption was as low as 0.2% to 0.6%, and further the values of the dielectric constant and the dissipation factor were low and the dielectric properties were excellent.

When the photopolymerization initiator, the thermal radical polymerization initiator, and if necessary the (meth)acryloyl compound (Examples 1 to 8) were used in combination with the resin including the aromatic polyester imide structure represented by Formula (1), the photosensitive resin composition, in which low dielectric properties were maintained and photolithography and insulating reliability were provided, was obtained, the cured product thereof exhibited good performance in terms of the low dielectric properties and the insulating property. Therefore the cured product thereof can be suitably used for an interlayer insulating film, a cover coat layer or a surface protective film.

### DESCRIPTION OF REFERENCE NUMERALS

1 Semiconductor substrate
2 Protective film
3 First conductive layer
4 Interlayer insulating film
5 Photosensitive resin layer
6A, 6B, 6C Window
7 Second conductive layer
8 Surface protective film

1. A photosensitive resin composition used for forming an insulating layer, the composition comprising a resin including an aromatic polyester imide structure represented by the following Formula (1), a photopolymerization initiator and a thermal radical polymerization initiator, wherein in a case in which the resin including an aromatic polyester imide structure represented by Formula (1) does not include a group represented by the following Formula (2), the resin composition includes a (meth)acryloyl compound: 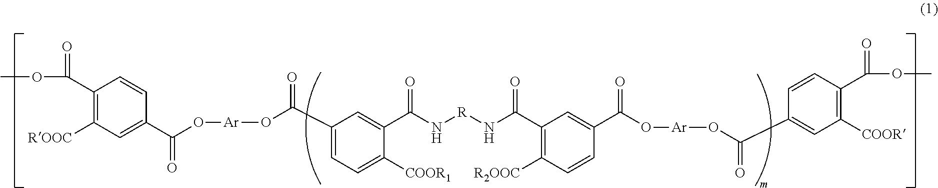
wherein, in Formula (1), m is an integer from 1 to 100, Ar is a divalent group having an aromatic skeleton, R is a divalent group having an aromatic skeleton with 2 to 30 carbon atoms and 4 to 100 hydrogen atoms, and each of —COOR₁ and —COOR₂ is positioned in an ortho position with an adjacent —CONH—, and each of R₁, R₂, and R′ independently represents a hydrogen atom, a group represented by Formula (2), or a hydrocarbon group with 1 to 4 carbon atoms: 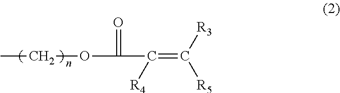
wherein, in Formula (2), each of R₃ to R₅ independently represents a hydrogen atom or an aliphatic hydrocarbon group with 1 to 3 carbon atoms, and n is an integer from 1 to 10.

2. The photosensitive resin composition according to claim 1, further comprising a coupling agent.

3. The photosensitive resin composition according to claim 1, further comprising a (meth)acryloyl compound.

4. The photosensitive resin composition according to claim 1, wherein a chloride ion concentration in a cured product of the photosensitive resin composition is 5 ppm or less.

5. The photosensitive resin composition according to claim 1, wherein a breaking elongation in a cured product of the photosensitive resin composition is from 10% to 200%.

6. The photosensitive resin composition according to claim 1, wherein a dielectric constant at 10 GHz in a cured product of the photosensitive resin composition is 3.2 or less.

7. The photosensitive resin composition according to claim 1, wherein a dissipation factor at 10 GHz in a cured product of the photosensitive resin composition is 0.0100 or less.

8. The photosensitive resin composition according to claim 1, wherein a weight reduction temperature by 5% in a cured product of the photosensitive resin composition is 300° C. or more.

9. The photosensitive resin composition according to claim 1, wherein a coefficient of moisture absorption in a cured product of the photosensitive resin composition, after being left in an environment of 130° C. and 85% relative humidity for 200 hours is 1% by mass or less.

10. A method of producing a patterned cured product, the method comprising:
forming a photosensitive resin film by applying the photosensitive resin composition according to claim 1 to a substrate and drying the photosensitive resin composition,
obtaining a resin film by pattern exposure of the photosensitive resin film,
obtaining a patterned resin film by developing the resin film after pattern exposure, using an organic solvent, and
heating the patterned resin film.

11. The method of producing a patterned cured product according to claim 10, wherein a heating temperature is 200° C. or less.

12. A cured product obtained by curing the photosensitive resin composition according to claim 1.

13. The cured product according to claim 12, which is a patterned cured product.

14. An interlayer insulating film comprising the cured product according to claim 12.

15. A cover coat layer comprising the cured product according to claim 12.

16. A surface protective film comprising the cured product according to claim 12.

17. An electronic component comprising the interlayer insulating film according to claim 14.

18. An electronic component comprising the cover coat layer according to claim 15.

19. An electronic component comprising the surface protective film according to claim 16.
